(19) United States
(12) Patent Application Publication
(10) Pub. No.: US 2017/0298507 A1
(43) Pub. Date: Oct. 19, 2017

(54) Semiconductor Fabrication Apparatus Including a Plurality of Reaction Containers and Methods of Forming Layers on Semiconductor Substrate Using the Same

(71) Applicant: Samsung Electronics Co., Ltd., Suwon-si (KR)

(72) Inventors: Soyoung Lee, Yongin-si (KR); Hyunsu Kim, Suwon-si (KR); Kiju Sohn, Gunpo-si (KR); Kuntack Lee, Suwon-si (KR); Jongwon Hong, Seoul (KR)

(21) Appl. No.: 15/398,284

(22) Filed: Jan. 4, 2017

(30) Foreign Application Priority Data
Apr. 18, 2016 (KR) 10-2016-0047063

(51) Int. Cl. C23C 16/455; H01L 27/115; H01L 21/768; H01L 21/02

(52) U.S. Cl. CPC C23C 16/45525; H01L 27/11582; H01L 21/0228; H01L 21/76831; H01L 27/11556

(57) ABSTRACT

A semiconductor fabrication apparatus can include a plurality of reaction containers that can be coupled together to provide a plurality of sequential respective stages in a process of generating a process gas for semiconductor fabrication, where each reaction container can include a respective semiconductor fabrication solid source material in a respective configuration that is different than in others of the reaction containers.

### CROSS-REFERENCE TO RELATED APPLICATION

This U.S. non-provisional patent application claims priority under 35U.S.C. §119 to Korean Patent Application No. 10-2016-0047063, filed on Apr. 18, 2016, in the Korean Intellectual Property Office, the entire disclosure of which is hereby incorporated herein by reference.

### FIELD

The present invention relates to semiconductor fabrication using solid source materials.

### BACKGROUND

Semiconductor processes (e.g., a deposition process) using a solid source material (i.e., solid source) may be performed when semiconductor devices are manufactured. Unlike a liquid source that can be centrally supplied, the solid source may be provided into an individual canister and the canister including the solid source may be supplied to an apparatus for performing the semiconductor process using the solid source. Since a supply amount of a process gas obtained from the solid source may be reduced according to a consumption amount of the solid source in the canister, a semiconductor process may be continuously performed by changing a process recipe or by replacing the canister with new one before the exhaustion of the solid source.

### SUMMARY

Embodiments according to the invention can provide a semiconductor fabrication apparatus with a plurality of reaction containers and methods of forming the layers on semiconductor substrates using the same. Pursuant to these embodiments, a semiconductor fabrication apparatus can include a plurality of reaction containers that can be coupled together to provide a plurality of sequential respective stages in a process of generating a process gas for semiconductor fabrication, where each reaction container can include a respective semiconductor fabrication solid source material in a respective configuration that is different than in others of the reaction containers.

In some embodiments, a semiconductor fabrication process canister comprising: a plurality of reaction containers coupled together in series to provide a plurality of sequential respective stages in a process of generating a process gas, wherein the plurality of sequential respective stages are configured with a sequence of increasing effective surface area of semiconductor fabrication solid source material exposed to the process in each of the plurality of sequential respective stages.

In some embodiments, a semiconductor fabrication process canister can include a plurality of reaction containers coupled together in series to provide a plurality of sequential respective stages in a process of generating a process gas, wherein the plurality of sequential respective stages can be configured with a sequence of decreasing initial masses of semiconductor fabrication solid source material.

In some embodiments, a semiconductor fabrication process canister can include a plurality of reaction containers coupled together in series to provide a plurality of sequential respective stages in a process of generating a process gas, wherein the plurality of sequential respective stages can be configured with a sequence of increasing effective surface area of semiconductor fabrication solid source material exposed to the process in each of the plurality of sequential respective stages.

In some embodiments, a semiconductor fabrication apparatus can include a plurality of reaction containers coupled together to provide a plurality of sequential respective stages in a process of generating a process gas for semiconductor fabrication, wherein a selected reaction container can be configured to provide a semiconductor fabrication solid source material recess having a depth that is greater than those of the reaction containers that are downstream from the selected reaction container in the process and the depth can be configured to be less than those of the reaction containers that are upstream from the selected reaction container in the process.

In some embodiments, a semiconductor fabrication apparatus can include a plurality of reaction containers coupled together to provide a plurality of sequential respective stages in a process of generating a process gas for semiconductor fabrication, wherein a selected reaction container can be configured to provide a semiconductor fabrication solid source material recess having a width that is less than those of the reaction containers that are downstream from the selected reaction container in the process and the width can be configured to be greater than those of the reaction containers that are upstream from the selected reaction container in the process.

In some embodiments, a method of forming a layer on a semiconductor wafer using a semiconductor fabrication apparatus can be provided by providing a carrier gas to an initial one of a plurality of reaction containers that are coupled together in series to provide a plurality of sequential respective stages, wherein each reaction container includes a respective semiconductor fabrication solid source material in a respective configuration that is different than in others of the reaction containers. A process gas can be generated by cumulative reactions in the plurality of sequential respective stages and the process gas can be provided from a last one of the plurality of reaction containers in the series to a semiconductor fabrication chamber housing the semiconductor wafer, and the layer can be formed on the semiconductor wafer using the process gas.

### BRIEF DESCRIPTION OF THE DRAWINGS

FIG. 1 is a schematic view illustrating a substrate-treating apparatus for performing a process using a solid source, according to some embodiments of the inventive concepts.

FIG. 2 is a schematic illustrating a phase change reaction of the solid source inside a canister, which occurs in a reaction space.

FIG. 3 is a schematic view illustrating an equivalent model of a canister according to some embodiments of the inventive concepts.

FIG. 4A is a schematic view illustrating a canister according to some embodiments of the equivalent model of FIG. 3.

FIG. 4B is a graph illustrating a flux rate of a gas source as a function of time provided by the canister of FIG. 4A.

FIG. 4C is a graph illustrating exhaustion time points of solid sources associated with the canister of FIG. 4A.

FIG. 4D is a schematic view illustrating a canister according to some embodiments of the equivalent model of FIG. 3.

FIG. 5 is a schematic view illustrating an equivalent model of a canister according to some embodiments of the inventive concepts.

FIG. 6A is a schematic view illustrating a canister according to some embodiments of the equivalent model of FIG. 5.

FIG. 6B is a schematic view illustrating a canister according to some embodiments of the equivalent model of FIG. 5.

FIG. 7 is a schematic view illustrating an equivalent model of a canister according to some embodiments of the inventive concepts.

FIG. 8 is a schematic view illustrating a canister according to some embodiments of the equivalent model of FIG. 7.

FIG. 9 is a flowchart illustrating methods of forming a layer on a substrate using the substrate-treating apparatus of FIG. 1.

FIGS. 10A and 10B are cross-sectional views illustrating a process of depositing a thin layer on a substrate, according to some embodiments of the inventive concepts.

### DETAILED DESCRIPTION OF THE EMBODIMENTS

The inventive concepts will now be described more fully hereinafter with reference to the accompanying drawings, in which example embodiments of the inventive concepts are shown. The inventive concepts and methods of achieving them will be apparent from the following example embodiments that will be described in more detail with reference to the accompanying drawings. The embodiments of the inventive concepts may, however, be embodied in different forms and should not be constructed as limited to the embodiments set forth herein. Rather, these embodiments are provided so that this disclosure will be thorough and complete, and will fully convey the scope of the inventive concepts to those skilled in the art.

As used herein, the singular terms “a”, “an”, and “the” are intended to include the plural forms as well, unless the context clearly indicates otherwise. It will be understood that when an element is referred to as being “connected” or “coupled” to another element, it may be directly connected or coupled to the other element or intervening elements may be present. As used herein, the term “and/or” includes any and all combinations of one or more of the associated listed items. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Example embodiments of aspects of the present inventive concepts explained and illustrated herein include their complementary counterparts. The same reference numerals or the same reference designators denote the same elements throughout the specification.

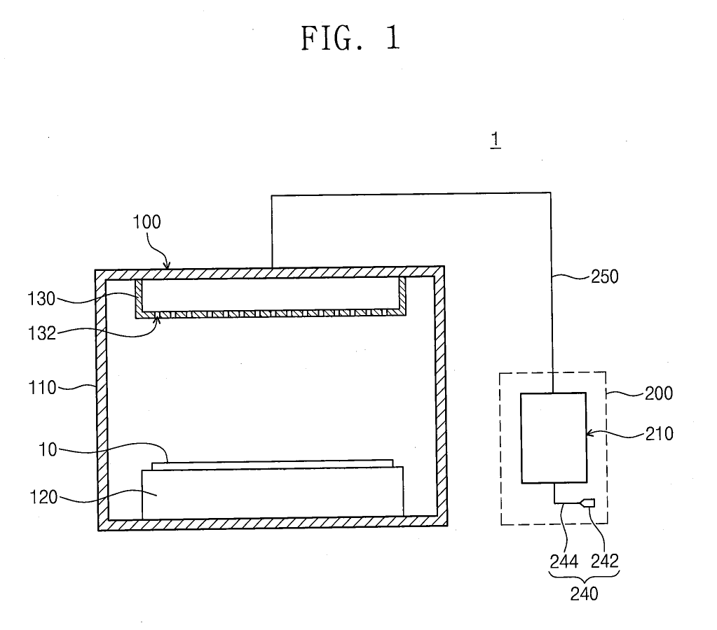

FIG. 1 is a schematic view illustrating a substrate-treating (or semiconductor fabrication) apparatus 1 configured to use a solid source material to form a layer on a substrate, according to some embodiments of the inventive concepts. A substrate-treating apparatus 1 may include a process chamber 100 and a gas supply unit 200. In some embodiments, a deposition process may be performed using a solid source material (i.e., solid source) in the substrate-treating apparatus 1. For example, the substrate-treating apparatus 1 may be a deposition apparatus in which a chemical vapor deposition (CVD) process or an atomic layer deposition (ALD) process is performed. However, embodiments of the inventive concepts are not limited thereto. In certain embodiments, at least one of other various processes using the solid source may be performed in the substrate-treating apparatus 1. In some embodiments, the substrate 10 may be a wafer. However, embodiments of the inventive concepts are not limited thereto. In certain embodiments, the substrate 10 may be any one of other various substrates.

Referring to FIG. 1, the process chamber 100 may include a housing 110, a support part 120, and a process gas supply part 130. The support part 120 may be disposed in the housing 110. The substrate 10 may be loaded on the support part 120, and a process may be performed on the substrate 10 loaded on the support part 120. The process gas supply part 130 may be disposed over the support part 120 and may face the support part 120. The process gas supply part 130 may be coupled to a top plate of the housing 110. The process gas supply part 130 may be supplied with a process gas through a gas supply line 250 of the gas supply unit 200, and the process gas may be provided to the substrate 10 loaded on the support part 120 through the process gas supply part 130. The process gas supply part 130 may include process gas supply holes 132. For example, the process gas supply part 130 may be a shower head.

The gas supply unit 200 may include a solid source part 210, a carrier gas supply part 240, and the gas supply line 250. A solid source may be stored in the inside of the solid source part 210. For example, the solid source may include HfCl₄. The solid source part 210 may be, for example, a canister. Hereinafter, the embodiment in which the solid source part 210 is described as a canister as an example. Particles of the solid source may be in powder form, but the solid source may be hardened to have a specific total volume.

The carrier gas supply part 240 may be connected to the canister 210. The carrier gas supply part 240 may supply a carrier gas to the canister 210. The carrier gas supply part 240 may include a carrier gas supply source 242 and a carrier gas supply line 244. The carrier gas may include a gas of which reactivity is low, e.g., an inert gas, and thus it may not react with the solid source. In some embodiments, the carrier gas may be a nitrogen (N₂) gas. However, embodiments of the inventive concepts are not limited thereto. In certain embodiments, the carrier gas may be an argon (Ar) gas or a helium (He) gas. The gas supply line 250 may be connected between the canister 210 and the process chamber 100, the process gas generated from the canister 210 may be supplied downstream into the process chamber 100 through the gas supply line 250. In some embodiments, the carrier gas supply line 244 and the gas supply line 250 may be coupled to opposite surfaces of the canister 210, respectively. However, embodiments of the inventive concepts are not limited thereto. In certain embodiments, the carrier gas supply line 244 and the gas supply line 250 may be coupled to the same surface of the canister 210. Even though not shown in the drawings, on-off valves may be installed on the gas supply line 250 and the carrier gas supply line 244, respectively. The carrier gas supply line 244 and the gas supply line 250 may correspond to an inlet and an outlet of the canister 210, respectively.

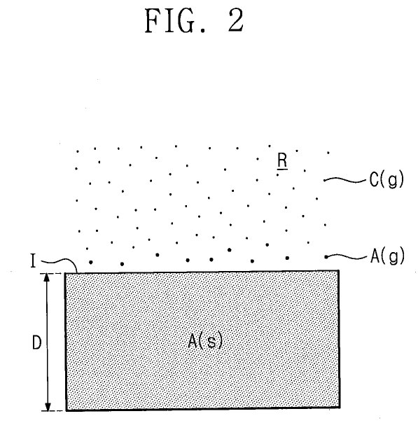

FIG. 2 is a schematic view of the inside of the canister 210 to illustrate a phase change reaction of the solid source, which occurs in a reaction space R. In FIG. 2, the reaction space R means a space in which the carrier gas C(g) and the solid source A(s) are provided. It will be understood that the reaction space n can correspond to a reaction container that can be configured to house a respective total initial mass of the solid source material. Referring to FIG. 2, the solid source A(s) may be heated to cause a sublimation reaction. The solid source A(s) may be sublimated at an interface I at which the carrier gas C(g) contacts the solid source A(s), and thus a gas source A(g) may be generated. The generated gas source A(g) may be mixed with the carrier gas C(g). At this time, the mixed gas of the gas source A(g) and the carrier gas C(g) is defined as the process gas supplied into the process chamber 100 downstream. The carrier gas C(g) may carry the gas source A(g) but may not react with the gas source A(g).

As described above, the sublimation reaction may occur at the interface I at which the carrier gas C(g) meets the solid source A(s). Thus, when a reaction rate of the solid source A(s) or the carrier gas C(g) at the interface I is increased, the sublimation reaction of the solid source A(s) may be accelerated. For example, the sublimation reaction may be accelerated by increasing physical dimensions such as a surface area of the interface I or surface areas of the particles of the solid source A(s). However, when a depth D of the solid source A(s) in the reaction space R is increased, a total surface area of the solid source A(s) may be increased but the surface area of the interface I may not be increased. Thus, the depth D of the solid source A(s) may not influence the reaction rate at the interface I. In other words, the increase in the depth D of the solid source A(s) contributes an increase in the amount of the solid source A(s) but does not contribute the increase in the reaction rate. Hereinafter, the surface area contributing the reaction at the interface I is defined as an effective surface area (E), and the effective surface area (E) of the solid source A(s) is distinguished from the total surface area of the solid source A(s). It will be further understood that other physical dimensions may be varied such as effective surface area, and the physical dimensions may be reflected by parameters of the canister such as width, depth, etc.

Various methods capable of accelerating a phase-change reaction in the canister 210 may be used to obtain the gas source A(g). In some embodiments, the effective surface area (E) of the solid source A(s) that is exposed to the process gas may be increased in the canister 210. For example, an inner space of the canister 210 may be divided and/or partitioned to increase the effective surface area (E) of the solid source A(s). The carrier gas C(g) may flow in one way through the canister 210. In other words, the carrier gas C(g) may have an irreversible flow in the canister 210. The inner space of the canister 210 may be divided along the flow of the carrier gas C(g) flowing into the canister 210. For example, a space dividing part P may be disposed in the canister 210 to divide an inner space of the canister 210 and to define a reaction space R. The space dividing part P may be provided in plurality. The n sub-space dividing parts P₁, P₂, P₃, . . . , Pₙ may define n sub-reaction spaces R₁, R₂, R₃, . . . , Rₙ, respectively.

It will be understood that the different sub-reaction spaces (or reaction containers) can be coupled together either as separate canisters or as different spaces within a single canister.

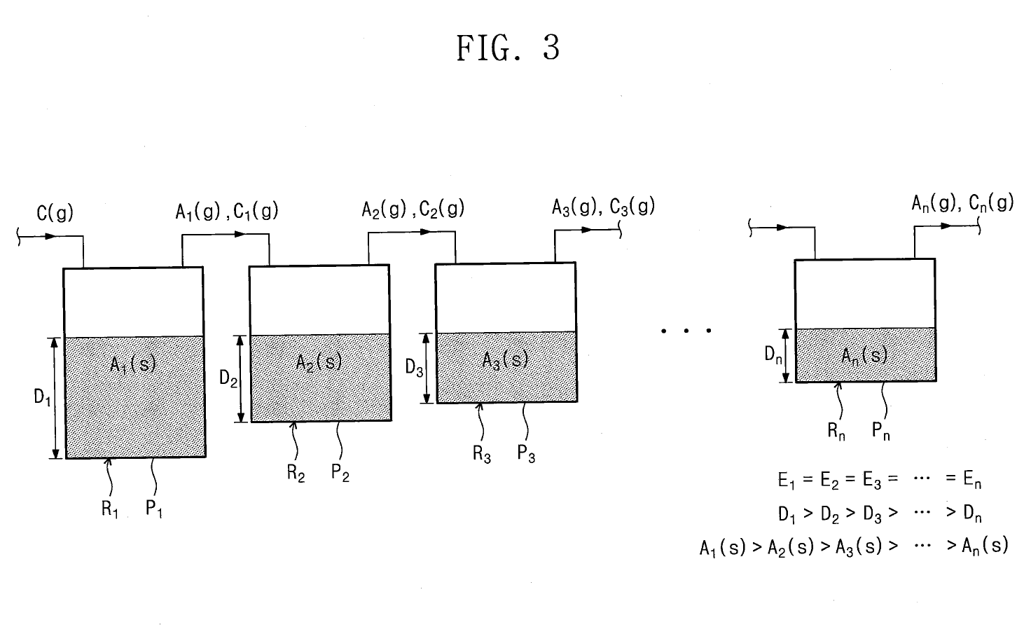

FIG. 3 is a schematic view illustrating an equivalent model of a canister 210 according to some embodiments of the inventive concepts. Referring to FIG. 3, sub-reaction spaces R₁, R₂, R₃, . . . , Rₙ may include solid sources A₁(s), A₂(s), A₃(s), . . . , Aₙ(s) of which the amounts (or mass) are different from each other (e.g., A₁(s)>A₂(s)>A₃(s)> . . . >Aₙ(s)). The solid sources A₁(s), A₂(s), A₃(s), . . . , Aₙ(s) may have depths D₁, D₂, D₃, . . . , Dₙ different from each other (e.g., D₁>D₂>D₃> . . . >Dₙ). Since the depths D₁, D₂, D₃, . . . , Dₙ of the solid sources A₁(s), A₂(s), A₃(s), . . . , Aₙ(s) in the first to n^{th} sub-reaction spaces R₁, R₂, R₃, . . . , Rₙ decrease in the order listed along a flow of a carrier gas C(g) (D₁>D₂>D₃> . . . >Dₙ), the amounts of the solid sources A₁(s), A₂(s), A₃(s), . . . , Aₙ(s) of the first to n^{th} sub-reaction spaces R₁, R₂, R₃, . . . , Rₙ may also decrease in the order listed (A₁(s)>A₂(s)>A₃(s)> . . . >Aₙ(s)). At this time, the amounts of the solid sources A₁(s), A₂(s), A₃(s), . . . , Aₙ(s) provided in the first to n^{th} sub-reaction spaces R₁, R₂, R₃, . . . , Rₙ may be different from each other, but effective surface areas E₁, E₂, E₃, . . . , Eₙ of the solid sources A₁(s), A₂(s), A₃(s), . . . , Aₙ(s) may be equal to each other (E₁=E₂=E₃= . . . =Eₙ). Accordingly, the sub-reaction spaces may each be configured to house a regulative total initial mass of the source material. In addition, other process conditions (e.g., pressure and/or temperature) of the first to n^{th} sub-reaction spaces R₁, R₂, R₃, . . . , Rₙ may be the same as each other.

According to some embodiments of the inventive concepts, the amount of the solid source of the sub-reaction space upstream in the flow of the carrier gas may be greater than the amount of the solid source of the downstream sub-reaction space relative to upstream in the flow of the carrier gas, and thus the exhaustion time point of the solid source of the prior sub-reaction space may be compensated. In other words, the solid sources of the reaction spaces may have consumption rates different from each other along the flow of the gas, but the amounts of the solid sources respectively provided in the reaction spaces may be adjusted such that the exhaustion time points of the solid sources of the reaction spaces may be the substantially same as each other. According, the physical dimensions of the reaction containers can be configured to compensate for the different consumption rates. At this time, the carrier gases C₁(g), C₂(g), C₃(g), . . . , Cₙ(g) respectively exhausted from the first to n^{th} sub-reaction spaces R₁, R₂, R₃, . . . , Rₙ may be the same gas, and the gas sources A₁(g), A₂(g), A₃(g), . . . , Aₙ(g) respectively exhausted from the first to n^{th} sub-reaction spaces R₁, R₂, R₃, . . . , Rₙ may be the same gas.

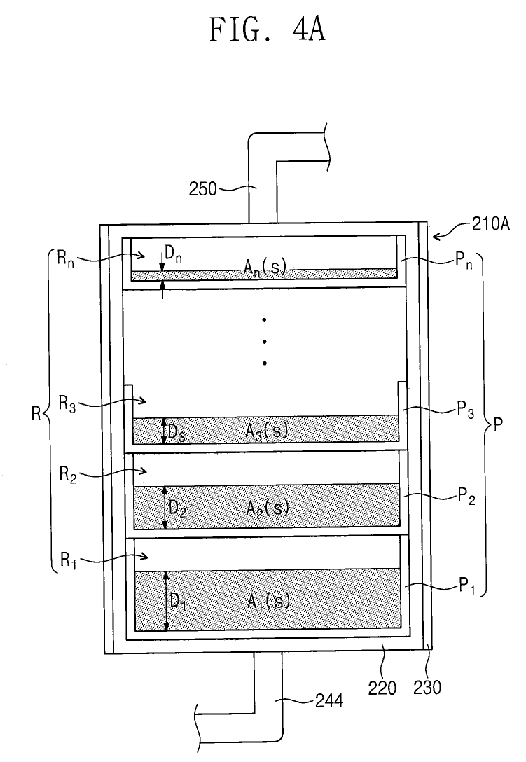

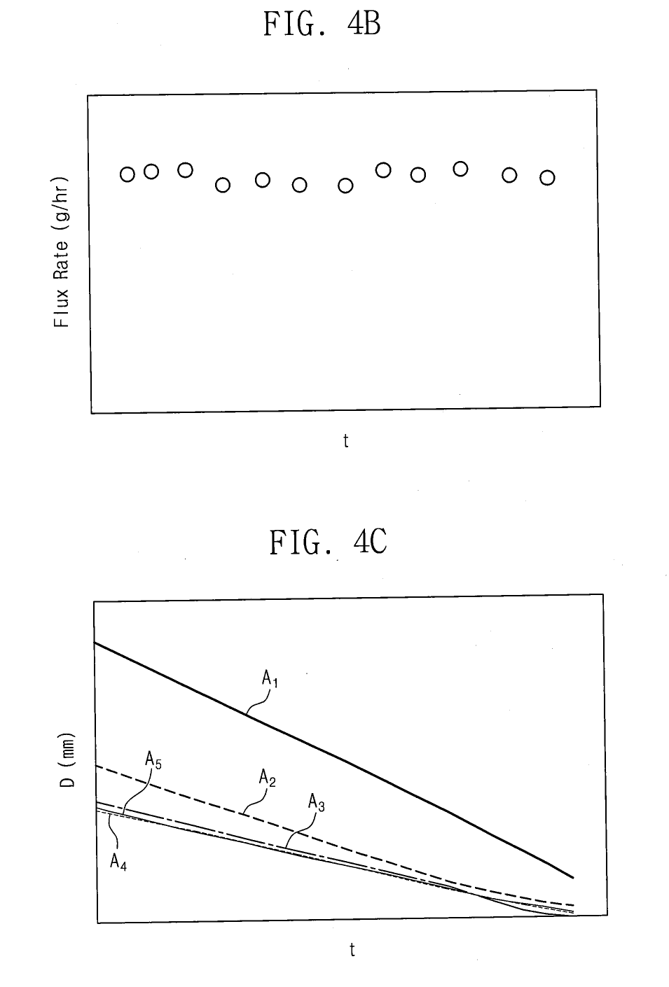

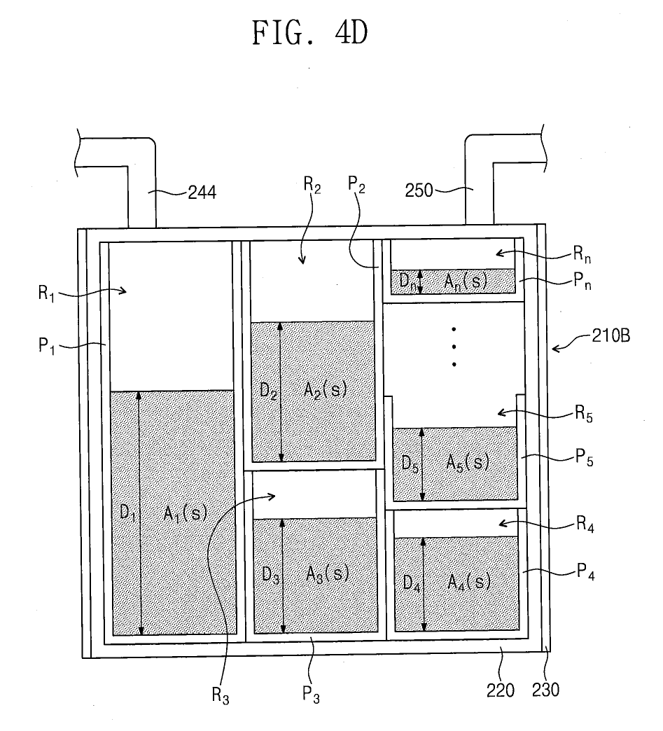

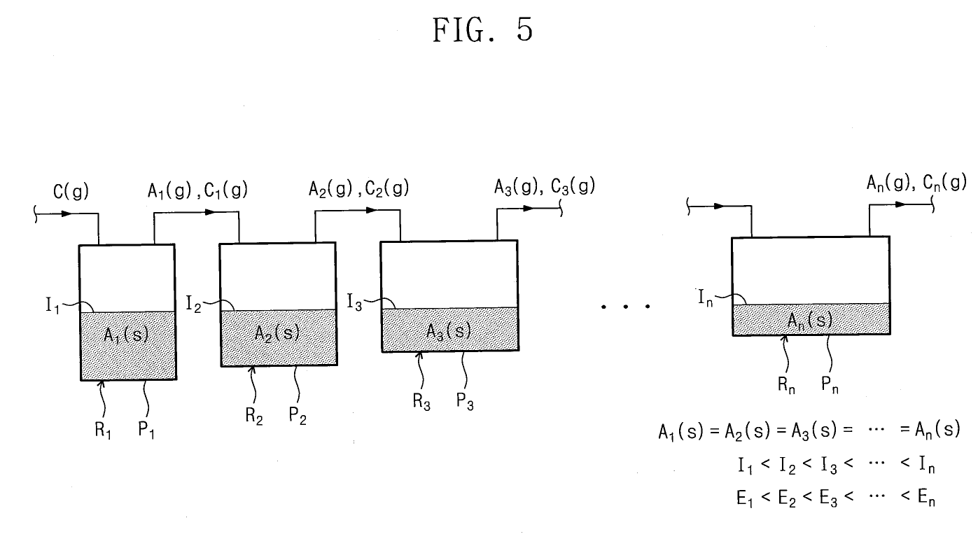

FIG. 4A is a schematic view illustrating a canister 210A according to some embodiments of the equivalent model of FIG. 3. The canister 210A may include a body 220, a space dividing part P, and a heater 230. The body 220 may have cylindrical shape. Alternatively, the body 220 may have a polygonal shape when viewed from a plan view. The body 220 may be formed of a material having heat-resistance characteristics and a high thermal conductivity. For example, the body 220 may include stainless steel. The heater 230 may surround the body 220. For example, the heater 230 may be a heater jacket. Alternatively, the heater 230 may include a coil.

The space dividing part P may be disposed in the body 220 to divide an inner space of the body 220 and to define a reaction space R. The space dividing part P may be, but not limited to, a tray. A plurality of space dividing parts P may be provided. The n sub-space dividing parts P₁, P₂, P₃, . . . , Pₙ may define n sub-reaction spaces (or reaction containers) R₁, R₂, R₃, . . . , Rₙ, respectively. A carrier gas supply 244 and a gas supply line 250 may be connected to opposite surfaces of the canister 210A, respectively. In some embodiments, the carrier gas supply line 244 may be coupled to a bottom surface of the canister 210A and the gas supply line 250 may be coupled to a top surface of the canister 210A, and thus a gas may flow from the bottom surface to the top surface of the canister 210A. The space dividing part P may include first to n^{th} sub-space dividing parts P₁, P₂, P₃, . . . , Pₙ arranged vertically along a height direction of the body 220.

In other words, the first to n^{th} sub-space dividing parts P₁, P₂, P₃, . . . , Pₙ may divide a reaction space R of the body 220 into sub-reaction spaces R₁, R₂, R₃, . . . , Rₙ. Depths D₁, D₂, D₃, . . . , Dₙ of solid sources A₁(s), A₂(s), A₃(s), . . . , Aₙ(s) respectively provided in the first to n^{th} sub-space dividing parts P₁, P₂, P₃, . . . , Pₙ may gradually decrease in the order listed (D₁>D₂>D₃> . . . >Dₙ. In other words, the amounts (or total initial mass) of the solid sources A₁(s), A₂(s), A₃(s), . . . , Aₙ(s) respectively provided in the first to n^{th} sub-space dividing parts P₁, P₂, P₃, . . . , Pₙ may gradually decrease in the order listed (A₁(s)>A₂(s)>A₃(s)> . . . >Aₙ(s)). To correspond to this, heights of the first to n^{th} sub-space dividing parts P₁, P₂, P₃, . . . , Pₙ may gradually decrease in the order listed as a distance from a top end of the body 220 decreases. However, embodiments of the inventive concepts are not limited thereto.

A carrier gas C(g) supplied from the carrier gas supply line 244 may sequentially move into the sub-reaction spaces R₁, R₂, R₃, . . . , Rₙ disposed on the carrier gas supply line 244. Each of the sub-reaction spaces R₁, R₂, R₃, . . . , Rₙ can be coupled together by inlet and outlet conduits. The carrier gas C(g) may carry gas sources A₁(g), A₂(g), A₃(g), . . . , Aₙ(g) generated in the sub-reaction spaces R₁, R₂, R₃, . . . , Rₙ while moving downstream through the sub-reaction spaces R₁, R₂, R₃, . . . , Rₙ. Process gases generated through the sub-reaction spaces R₁, R₂, R₃, . . . , Rₙ may be exhausted into the gas supply line 250 and may be supplied into a process chamber through the gas supply line 250. Since the inner space of the canister 210A is divided into a plurality of the sub-reaction spaces R₁, R₂, R₃, . . . , Rₙ as described above, the effective surface area (E) of the solid source A(s) may be increased to obtain more of the gas source A(g). Fine holes may be provided in the sub-space dividing parts P₁, P₂, P₃, . . . , Pₙ to induce the flows of the gases. The hardened solid source may be provided as described above, and thus a loss of the solid source by the fine holes may be reduced. Alternatively, an additional gas flow path (e.g., an induction pipe) inducing a gas flow may be disposed in the reaction space R. Hereinafter, the same elements as described with reference to FIGS. 2 and 4A will be indicated by the same reference numerals or the same reference designators, and the descriptions thereto may be omitted or mentioned briefly for the purpose of ease and convenience in explanation.

FIG. 4B is a graph illustrating a flux rate of a gas source A(g) according to a time when the canister 210A of FIG. 4A is used. FIG. 4C is a graph illustrating exhaustion time points of solid sources when the canister 210A of FIG. 4A is used. The canister 210A including five sub-reaction spaces R₁, R₂, R₃, R₄, and R₅ and five solid sources A₁, A₂, A₃, A₄, and A₅ is illustrated as an example in FIG. 4C. Referring to FIG. 4B, it is recognized that the flux rate of the gas source A(g) obtained from the canister 210A according to the inventive concepts is substantially uniform as time passes. Referring to FIG. 4C, it is recognized that exhaustion time points of the solid sources A₁, A₂, A₃, A₄, and A₅ are similar to each other since initial depths D₁, D₂, D₃, . . . , Dₙ of the solid sources A₁, A₂, A₃, A₄, and A₅ are different from each other (D₁>D₂>D₃> . . . >Dₙ)to provide different total initial masses according to some embodiments of the inventive concepts. In other words, the exhaustion time points of the solid sources A₁, A₂, A₃, A₄, and A₅ may be adjusted to be the substantially same as each other, and thus the uniform amount of the gas source A(g) may be obtained even though time passes.

FIG. 4D is a schematic view illustrating a canister 210B according to some embodiments of the equivalent model of FIG. 3. A carrier gas supply line 244 and a gas supply line 250 may be connected to the same surface of the canister 210B. Thus, a carrier gas may flow into the canister 210B through one plate of the canister 210B and may flow out of the canister 210B through the one plate of the canister 210B. For example, in the embodiment of FIG. 4D, the carrier gas may flow into the canister 210B through a top plate of the canister 210B and then may circulate within the canister 210B. Thereafter, the carrier gas may flow out of the canister 210B through the top plate of the canister 210B. Thus, the space dividing part P may include first to n^{th} sub-space dividing parts P₁, P₂, P₃, P₄, P₅, . . . , Pₙ arranged along the flow of the carrier gas. In other words, the reaction space R of the body 220 of the canister 210A of FIG. 4A may include the sub-reaction spaces which are vertically divided, but the reaction space R of the body 220 of the canister 210B of FIG. 4D may include sub-reaction spaces which are vertically and horizontally divided. Depths D₁, D₂, D₃, D₄, D₅, . . . , Dₙ of solid sources A₁(s), A₂(s), A₃(s), A₄(s), A₅(s), . . . , Aₙ(s) respectively provided in the sub-space dividing parts P₁, P₂, P₃, P₄, P₅, . . . , Pₙ may gradually decrease in the order listed (D₁>D₂>D₃>D₄>D₅> . . . >Dₙ). In other words, the total initial masses of the solid sources A₁(s), A₂(s), A₃(s), A₄(s), A₅(s), . . . , Aₙ(s) respectively provided in the sub-space dividing parts P₁, P₂, P₃, P₄, P₅, . . . , Pₙ may gradually decrease in the order listed (A₁(s)>A₂(s)>A₃(s)>A₄(s)>A₅(s)> . . . >Aₙ(s)).

The structures of the canisters 210A and 210B described with reference to FIGS. 3, 4A, and 4D may include the solid sources of which the amounts (or total initial masses) are different from each other along the flow of the carrier gas. In some embodiments, the amount (or mass) of the solid source in upstream sub-reaction spaces in the flow of the carrier gas may be greater than the mass of the solid source in downstream sub-reaction spaces relative to the upstream sub-reaction spaces. In these embodiments, the amounts (or total initial masses) of the solid sources may be adjusted by changing the depths of the solid sources to explain the solid sources of which the amounts are different from each other in a state in which the effective surface areas of the solid sources are equal to each other. However, embodiments of the inventive concepts are not limited thereto. In certain embodiments, the amounts (or total initial masses) of the solid sources may be adjusted by at least one of other various methods. In addition, embodiments of the inventive concepts are not limited to the method of dividing the inner space of the canister and the number of the sub-reaction spaces, described above. Furthermore, differences between the amounts of the solid sources respectively provided in the sub-reaction spaces may be continuous or discontinuous.

However, when the first to n^{th} sub-reaction spaces divided by the space dividing part P may include the solid sources of which the amounts are same with each other along the flow of the carrier gas, the amounts of the gas sources exhausted from the first to n^{th} sub-reaction spaces R₁, R₂, R₃, . . . , Rₙ may increase in the order listed (A₁(g)<A₂(g)<A₃(g)< . . . <Aₙ(g)) by providing the carrier gas C(g) sequentially. On the contrary, the amounts of the carrier gases exhausted from the first to n^{th} sub-reaction spaces may decrease in the order listed (C₁(g)>C₂(g)>C₃(g)> . . . >Cₙ(g)) and then relative concentrations of the carrier gases C₁(g), C₂(g), C₃(g), . . . , Cₙ(g) in the first to n^{th} sub-reaction spaces R₁, R₂, R₃, . . . , Rₙ may decrease in the order listed. Since the relative concentrations of the carrier gases in the first to n^{th} sub-reaction spaces R₁, R₂, R₃, . . . , Rₙ decrease in the order listed, reaction rates (e.g., sublimation rates) of the solid sources A₁(s), A₂(s), A₃(s), . . . , Aₙ(s) in the first to n^{th} sub-reaction spaces R₁, R₂, R₃, . . . , Rₙ may be different from each other. Thus, the exhaustion time points of the solid sources A₁(s), A₂(s), A₃(s), . . . , Aₙ(s) in the first to n^{th} sub-reaction spaces R₁, R₂, R₃, . . . , Rₙ may be different from each other.

In other words, as appreciated by the present inventors, a difference between the concentrations of the carrier gases in the reaction spaces (i.e., reaction container) may cause a difference between the reaction rates of the solid sources in the reaction spaces, and the difference between the reaction rates of the solid sources may cause a difference between exhaustion time points of the solid sources respectively provided in the reaction spaces if unaddressed. In addition, the amount of the obtained gas source may be varied according to a time. In particular, the flux rate of the gas source may be reduced, and thus a thickness of a deposited layer formed on a substrate 10 may be reduced. However, according to some embodiments of the inventive concepts, a difference in reaction rate between reaction spaces may be reduced or compensated such that the canisters 210A, 210B can supply a substantially uniform amount of the gas source A(g) regardless of a flow of time/gas or the amount of the solid source.

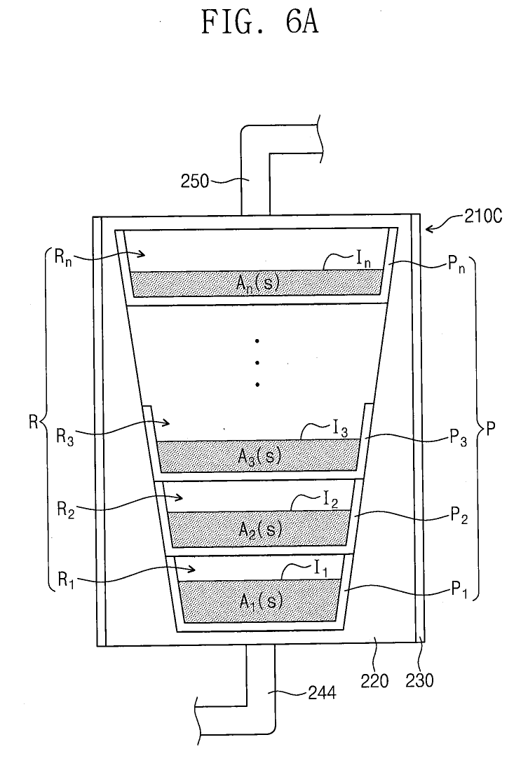

FIG. 5 is a schematic view illustrating an equivalent model of a canister according to some embodiments of the inventive concepts. Referring to FIG. 5, a physical dimension of the areas of interfaces I₁, I₂, 1₃, . . . , Iₙ of solid sources A₁(s), A₂(s), A₃(s), . . . , Aₙ(s) respectively provided in sub-reaction spaces (i.e., reaction containers) R₁, R₂, R₃, . . . , Rₙ may increase in the order listed along the flow of the carrier gas C(g) (I₁<I₂<I₃< . . . <Iₙ). In other words, effective surface areas E₁, E₂, E₃, . . . , Eₙ of the solid sources A₁(s), A₂(s), A₃(s), . . . , Aₙ(s) respectively provided in the first to n^{th} sub-reaction spaces R₁, R₂, R₃, . . . , Rₙ may increase in the order listed (E₁<E₂<E₃< . . . <Eₙ). Since the solid source A(s) is sublimated at the interface I at which the carrier gas C(g) is in contact with the solid source A(s), the amount of the gas source A(g) may be increased by increasing the area of the interface I. At this time, process conditions (e.g., the amounts, pressures, and/or temperatures) of the solid sources A₁(s), A₂(s), A₃(s), . . . , Aₙ(s) respectively provided in the sub-reaction spaces R₁, R₂, R₃, . . . , Rₙ may be equal to each other.

Since the areas of the interfaces (i.e., the effective surface areas) of the first to n^{th} sub-reaction spaces R₁, R₂, R₃, . . . , Rₙ gradually increase in the order listed (E₁<E₂<E₃< . . . <Eₙ), the amounts of the gas sources A₁(g), A₂(g), A₃(g), . . . , Aₙ(g) generated from the first to n^{th} sub-reaction spaces R₁, R₂, R₃, . . . , Rₙ may also increase in the order listed (A₁(g)<A₂(g)<A₃(g)< . . . <Aₙ(g)). In other words, the effective surface area of the downstream sub-reaction space may be greater than that of the upstream reaction containers, and thus differences between reaction rates in the reaction containers may be reduced or compensated.

According to the present embodiment, since the reaction rate of the downstream sub-reaction space is increased by increasing the effective surface area of the solid source, the differences between the reaction rates of the sub-reaction spaces may be reduced or compensated. When the reaction rates of the sub-reaction spaces are substantially uniform, exhaustion time points of the solid sources of the sub-reaction spaces may be the substantially same as each other. Thus, it is possible to reduce or compensate reduction in flux rate of the obtained gas source, which may be caused as time passes.

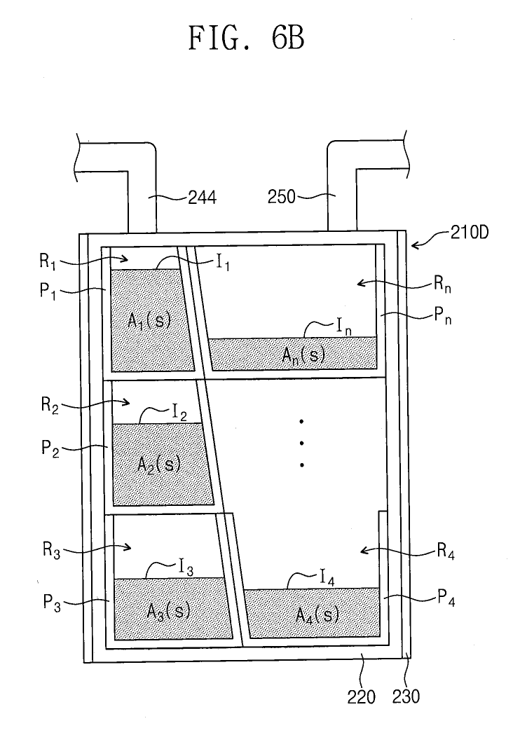

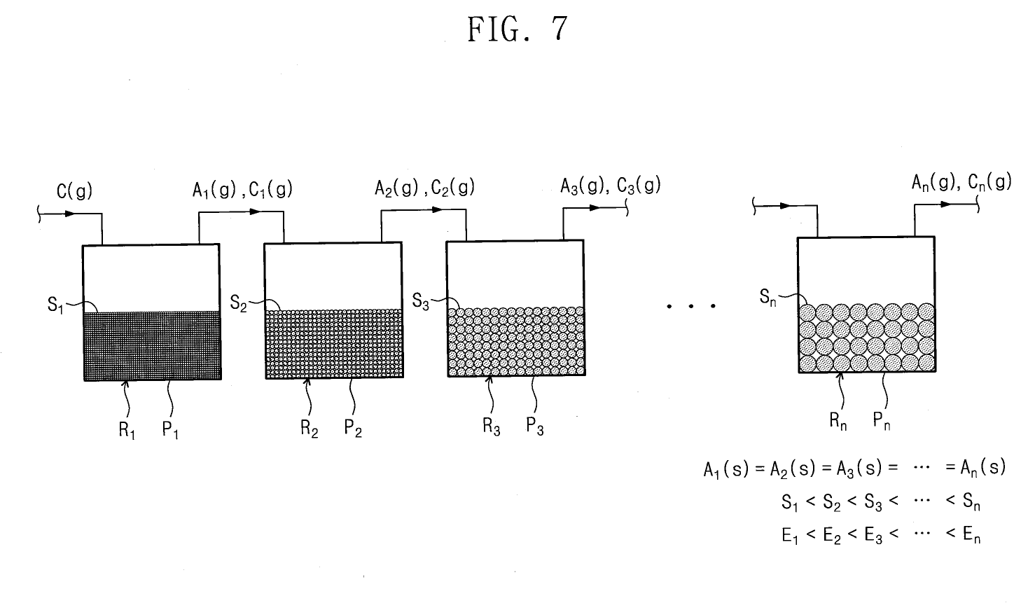

FIG. 6A is a schematic view illustrating a canister 210C according to some embodiments of the equivalent model of FIG. 5. The canister 210C may include a body 220, a space dividing part P, and a heater 230. A carrier gas supply line 244 and a gas supply line 250 may be connected to opposite surfaces of the canister 210C, respectively. In some embodiments, as illustrated in FIG. 6A, the carrier gas supply 244 may be coupled to a bottom surface of the canister 210C and the gas supply 250 may be coupled to a top surface of the canister 210C, and thus a gas (e.g., a carrier gas) may flow from the bottom surface of the canister 210C to the top surface of the canister 210C. Thus, the space dividing part P may include first to n^{th} sub-space dividing parts P₁, P₂, P₃, . . . , Pₙ arranged along a height direction of the body 220. Widths (e.g., areas of interfaces I₁, I₂, I₃, . . . , Iₙ) of the first to n^{th} sub-space dividing parts P₁, P₂, P₃, . . . , Pₙ may increase in the order listed (I₁<I₂<I₃< . . . <Iₙ) as a distance from a top end of the body 220 decreases. Since the areas of the interfaces I₁, I₂, I₃, . . . , Iₙ of the first to n^{th} sub-space dividing parts P₁, P₂, P₃, . . . , Pₙ gradually increase in the order listed (I₁<I₂<I₃< . . . <Iₙ), effective surface areas E₁, E₂, E₃, . . . , Eₙ of solid sources A₁(s), A₂(s), A₃(s), . . . , Aₙ(s) respectively provided in the first to n^{th} sub-space dividing parts P₁, P₂, P₃, . . . , Pₙ may also increase in the order listed (E₁<E₂<E₃< . . . <Eₙ). The amounts of the solid sources A₁(s), A₂(s), A₃(s), . . . , Aₙ(s) in the first to n^{th} sub-space dividing parts P₁, P₂, P₃, . . . , Pₙ may be equal to each other (A₁(s)=A₂(s)=A₃(s)=, . . . , =Aₙ(s)).

FIG. 6B is a schematic view illustrating a canister 210D according to some embodiments of the equivalent model of FIG. 5. A carrier gas supply line 244 and the gas supply line 250 may be connected to the same surface of the canister 210D. A carrier gas may flow into the canister 210D through one plate of the canister 210D and then may flow out of the canister 210D through the one plate of the canister 210D. For example, in the embodiment of FIG. 6B, the carrier gas may flow into the canister 210D through a top plate of the canister 210D and then may circulate within the canister 210D. Thereafter, the carrier gas may flow out of the canister 210D through the top plate of the canister 210D. Thus, the space dividing part P may include first to n^{th} sub-space dividing parts P₁, P₂, P₃, P₄, . . . , Pₙ arranged along the flow of the carrier gas. In other words, the reaction space R of the body 220 of the canister 210C of FIG. 6A may include the sub-reaction spaces which are vertically divided, but the reaction space R of the body 220 of the canister 210D of FIG. 6B may include sub-reaction spaces which are vertically and horizontally divided. Areas of interfaces I₁, I₂, I₃, I₄, . . . , Iₙ of solid sources A₁(s), A₂(s), A₃(s), A₄(s) . . . , Aₙ(s) respectively provided in the first to n^{th} sub-space dividing parts P₁, P₂, P₃, P₄, . . . , Pₙ may gradually increase in the order listed (I₁<I₂<I₃<I₄< . . . <Iₙ). In other words, effective surface areas E₁, E₂, E₃, E₄, . . . , Eₙ of the solid sources A₁(s), A₂(s), A₃(s), A₄(s) . . . , Aₙ(s) respectively provided in the first to n^{th} sub-space dividing parts P₁, P₂, P₃, P₄, . . . , Pₙ may gradually increase in the order listed (E₁<E₂<E₃<E₄< . . . <Eₙ). The amounts of the solid sources A₁(s), A₂(s), A₃(s), A₄(s) . . . , Aₙ(s) respectively provided in the sub-space dividing parts P₁, P₂, P₃, P₄, . . . , Pₙ may be equal to each other (A₁(s)=A₂(s)=A₃(s)=A₄(s)= . . . =Aₙ(s)).

The structures of the canisters 210C and 210D described with reference to FIGS. 5, 6A, and 6B may include the solid sources of which the effective surface areas are different from each other along the flow of the carrier gas. In some embodiments, the area of the interface of the solid source in the sub-reaction spaces downstream in the flow of the carrier gas may be greater than the area of the interface of the solid source in the upstream sub-reaction spaces in the flow of the carrier gas. In these embodiments, the amounts of the solid sources may be equal to each other to explain the effect obtained from the areas of the interfaces which are different from each other. However, embodiments of the inventive concepts are not limited thereto. In addition, embodiments of the inventive concepts are not limited to the method of dividing the inner space of the canister and the number of the sub-reaction spaces, described in these embodiments. Furthermore, differences between the areas of the interfaces of the solid sources in the sub-reaction spaces may be continuous or discontinuous.

However, as appreciated by the present inventors, if the first to n^{th} sub-reaction spaces divided by the space dividing part P may include the solid sources of which the effective surface areas are same with each other along the flow of the carrier gas, the reaction rate of the downstream sub-reaction space is less than that of the upstream sub-reaction space. If unaddressed, a difference between the reaction rates of the solid sources may cause a difference between exhaustion time points of the solid sources respectively provided in the reaction spaces. In addition, the amount of the obtained gas source may be varied according to a time. In particular, the flux rate of the gas source may be reduced, and thus a thickness of a deposited layer formed on a substrate 10 may be reduced. However, according to some embodiments of the inventive concepts, a difference in reaction rate between reaction spaces may be reduced or compensated such that the canisters 210C, 210D can supply a substantially uniform amount (or composition) of the gas source A(g) regardless of a flow of time/gas or the filling amount of the solid source.

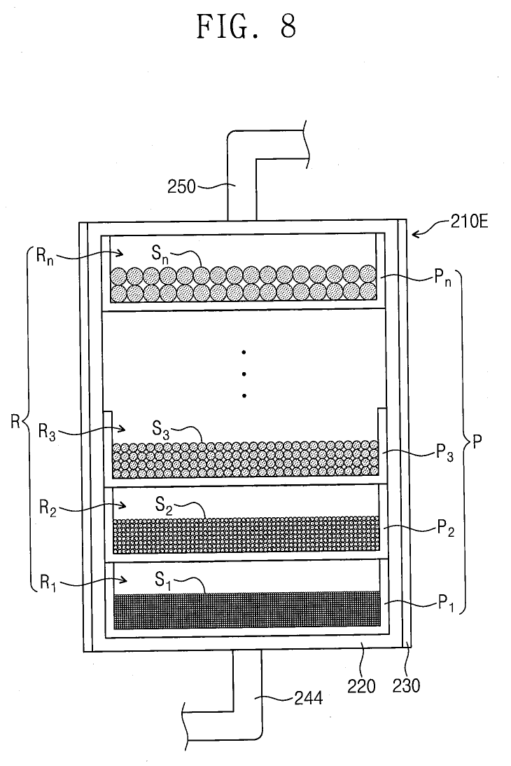

FIG. 7 is a schematic view illustrating an equivalent model of a canister 210 according to some embodiments of the inventive concepts. Referring to FIG. 7, the physical dimension of the effective surface areas of solid sources in sub-reaction spaces (reaction containers) R₁, R₂, R₃, . . . , Rₙ may be different from each other along a flow of a carrier gas C(g). In some embodiments, sizes of particles of first to n^{th} solid sources respectively provided in first to n^{th} sub-reaction spaces R₁, R₂, R₃, . . . , Rₙ may increase in the order listed (S₁<S₂<S₃< . . . <Sₙ). Thus, the effective surface areas of the first to n^{th} solid sources in the first to n^{th} sub-reaction spaces R₁, R₂, R₃, . . . , Rₙ may increase in the order listed (E₁<E₂<E₃< . . . <Eₙ). In other words, the reaction rate of the solid source may be increased by increasing a surface area of the particle of the solid source. At this time, other process conditions (e.g., the amounts, pressures, and/or temperatures) of the sub-reaction spaces R₁, R₂, R₃, . . . , Rₙ may be equal to each other. It will be understood that the total initial mass of the source material in the reaction containers may be about the same even though the particle size may be different.

Since the sizes of the particles (i.e., the effective surface areas) of the solid sources of the first to n^{th} sub-reaction spaces R₁, R₂, R₃, . . . , Rₙ may increase in the order listed (E₁<E₂<E₃< . . . <Eₙ), the amounts of gas sources A₁(g), A₂(g), A₃(g), . . . , Aₙ(g) respectively obtained from the first to n^{th} sub-reaction spaces R₁, R₂, R₃, . . . , Rₙ may increase in the order listed (A₁(g)<A₂(g)<A₃(g)< . . . <Aₙ(g)). In other words, since the particle size of the solid source provided in the downstream sub-reaction space is greater than that of the solid source provided in the upstream sub-reaction space, a difference between the reaction rates of the sub-reaction spaces may be reduced or compensated.

According to the present embodiment, since the reaction rate of the downstream sub-reaction space is increased by increasing the particle size of the solid source, the differences between the reaction rates of the sub-reaction spaces may be reduced or compensated. When the reaction rates of the sub-reaction spaces are substantially uniform, exhaustion time points of the solid sources of the sub-reaction spaces may be the substantially same as each other. Thus, it is possible to reduce or compensate reduction in flux rate of the obtained gas source, which may be caused as time passes.

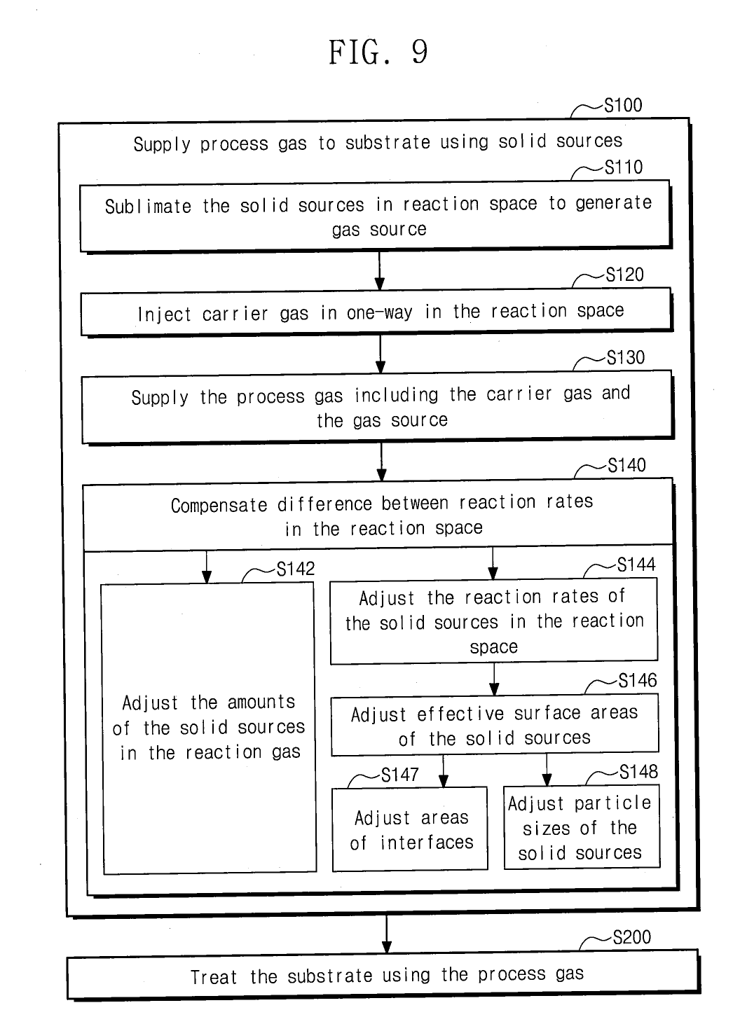

FIG. 8 is a schematic view illustrating a canister 210E according to some embodiments of the equivalent model of FIG. 7. The canister 210E may include a body 220, a space dividing part P, and a heater 230. A carrier gas supply line 244 and a gas supply line 250 may be connected to opposite surfaces of the canister 210E, respectively. In the embodiment of FIG. 8, the carrier gas supply line 244 may be coupled to a bottom surface of the canister 210E and the gas supply line 250 may be coupled to a top surface of the canister 210E, and thus a gas (e.g., a carrier gas) may flow from the bottom surface to the top surface of the canister 210E. Thus, the space dividing part P may include first to n^{th} sub-space dividing parts P₁, P₂, P₃, . . . , Pₙ arranged along a vertical height direction of the body 220. Particle sizes of solid sources respectively provided in the first to n^{th} sub-space dividing parts P₁, P₂, P₃, . . . , Pₙ may gradually increase in the order listed (S₁<S₂<S₃< . . . <Sₙ). Since the particle sizes of the solid sources of the first to n^{th} sub-space dividing parts P₁, P₂, P₃, . . . , Pₙ gradually increase in the order listed (S₁<S₂<S₃< . . . <Sₙ), effective surface areas of the solid sources of the first to n^{th} sub-space dividing parts P₁, P₂, P₃, . . . , Pₙ may also increase in the order listed (E₁<E₂<E₃< . . . <Eₙ). The amounts of the solid sources of the sub-space dividing parts P₁, P₂, P₃, . . . , Pₙ may be equal to each other (A₁(s)=A₂(s)=A₃(s)= . . . =Aₙ(s)).

The structure of the canister 210E described with reference to FIGS. 7 and 8 may include the solid sources of which the effective surface areas are different from each other along the flow of the carrier gas. In some embodiments, the particle size of the solid source distant from the start point of the flow of the carrier gas may be greater than the particle size of the solid source near to the start point of the flow of the carrier gas. In these embodiments, the amounts of the solid sources may be equal to each other to explain the effect obtained from the different particle sizes. However, embodiments of the inventive concepts are not limited thereto. In addition, embodiments of the inventive concepts are not limited to the method of dividing the inner space of the canister and the number of the sub-reaction spaces, described in these embodiments. Furthermore, differences between the particle sizes of the solid sources may be continuous or discontinuous.

In the aforementioned embodiments, the amounts of the solid sources may be different from each other along the gas flow in the reaction space, the areas of the interfaces of the solid sources may be different from each other along the gas flow in the reaction space, and/or the particle sizes of the solid sources may be different from each other along the gas flow in the reaction space. The embodiments described above may be combined with one another.

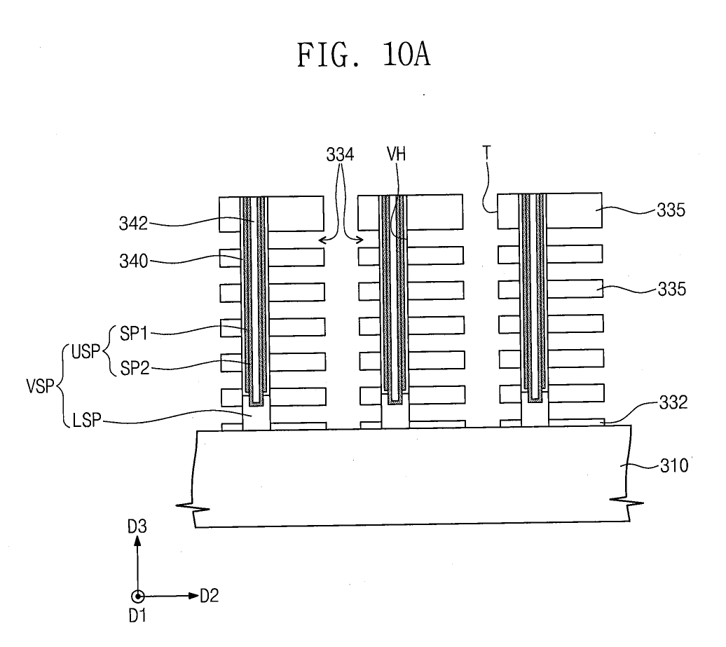

FIG. 9 is a flowchart illustrating a method of treating a substrate by using the substrate-treating apparatus 1 of FIG. 1. The canister 210 of FIG. 1 may be any one of the canisters 210A, 210B, 210C, 210D, and 210E. Referring to FIGS. 1 and 9, a process gas may be supplied to a substrate 10 by using a solid source (S100), and the substrate 10 may be treated using the process gas (S200). In some embodiments, the process of treating the substrate 10 may be a process of depositing a thin layer on the substrate 10. Hereinafter, the operation S100 of supplying the process gas to the substrate 10 will be described in detail. First, the solid source may be sublimated in the reaction space of the canister 210 to generate a gas source (S110). A carrier gas may be injected in one-way in the reaction space (S120). The carrier gas may carry the gas source, and thus the process gas in which the carrier gas and the gas source are mixed with each other may be supplied into the process chamber 100 (S130). At this time, the gases may flow in the irreversible one-way in the canister 210, and a difference between the reaction rates may occur along the one-way. In more detail, a reaction rate of the solid source provided in an upstream sub-reaction space near to a start point of the flow of the gases may be greater than that of the solid source provided in a downstream sub-reaction space distant from the start point of the flow of the gases, and thus the solid source of the upstream sub-reaction space may be exhausted before exhaustion of the solid source of the downstream sub-reaction space. According to some embodiments of the inventive concepts, the difference between the reaction rates may be compensated (S140).

In some embodiments, the amounts of the solid sources provided in the reaction space may be adjusted to reduce or compensate the difference between the reaction rates (S142). In detail, as described above, the solid source of the upstream sub-reaction space may be exhausted before exhaustion of the solid source of the downstream sub-reaction space since the reaction rate of the solid source of the upstream sub-reaction space is higher than that of the solid source of the downstream sub-reaction space. Thus, the amount of the solid source of the upstream sub-reaction space may be adjusted to be greater than that of the solid source of the downstream sub-reaction space. As a result, exhaustion time points of the solid sources of the sub-reaction spaces may be the substantially same as each other.

In certain embodiments, the reaction rates of the solid sources in the reaction space may be adjusted (S144). In detail, since the reaction rate of the solid source of the upstream sub-reaction space is greater than that of the solid source of the downstream sub-reaction space, the reaction rates may be adjusted to be the substantially same as each other by reducing the reaction rate of the solid source of the upstream sub-reaction space or by increasing the reaction rate of the solid source of the downstream sub-reaction space. In some embodiments, the effective surface areas of the solid sources may be adjusted (S146). For example, physical dimensions of the reaction containers such as the areas of the interfaces at which the phase-change reactions of the solid sources may be adjusted (S147), or particle sizes of the solid sources may be adjusted (S148).

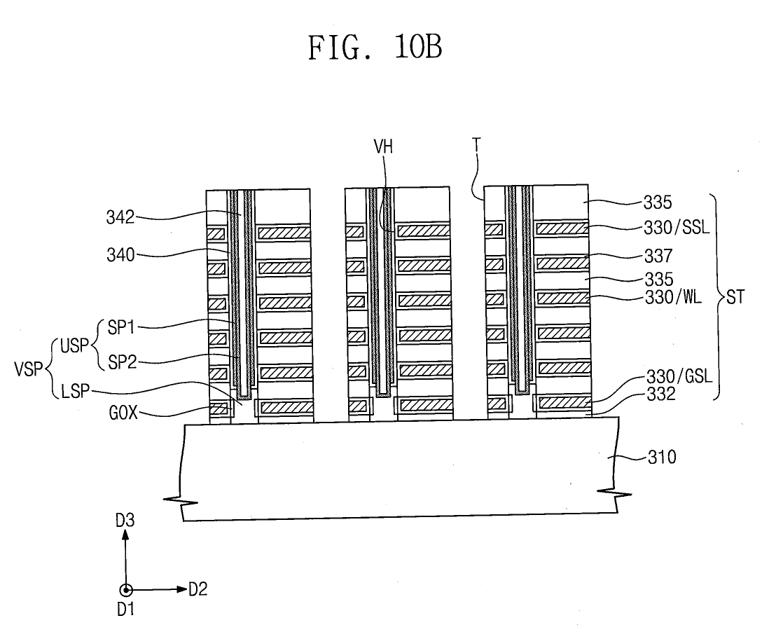

FIGS. 10A and 10B are cross-sectional views illustrating a process of depositing a thin layer on a substrate 310, according to some embodiments of the inventive concepts. Referring to FIG. 10A, a vertical semiconductor pattern VSP including an upper semiconductor pattern USP and a lower semiconductor pattern LSP may be formed on the substrate 310. The upper semiconductor pattern USP may include a first semiconductor pattern SP1 and a second semiconductor pattern SP2.

In more detail, a buffer dielectric layer 332 may be formed on the substrate 310, and sacrificial layers and insulating layers 335 may be alternately and repeatedly formed on the buffer dielectric layer 332. Vertical holes VH may be formed to penetrate the sacrificial layers and the insulating layers 335. The lower semiconductor pattern LSP may be formed to fill a lower region of each of the vertical holes VH. A data storage structure 340, the first semiconductor pattern SP1, the second semiconductor pattern SP2, and a filling insulator 342 which are sequentially stacked may be formed on the lower semiconductor pattern LSP in each of the vertical holes VH. Thereafter, the insulating layers 335, the sacrificial layers, and the buffer dielectric layer 332 may be sequentially patterned to form isolation trenches T. The sacrificial layers exposed by the isolation trenches T may be selectively removed to form gate regions 334.

Referring to FIG. 10B, the lower semiconductor patterns LSP exposed by the gate regions 334 may be thermally oxidized to form gate oxide layers GOX on sidewalls of the lower semiconductor patterns LSP, and insulating patterns 337 may be formed on the insulating layers 335 and the data storage structures 340 exposed through the gate regions 334. The insulating patterns 337 may be formed using an atomic layer deposition (ALD) process. In other words, the insulating patterns 337 may be formed using the solid sources (e.g., HfCl₄) by the substrate-treating apparatus 1 according to some embodiments of the inventive concepts. The insulating pattern 337 may include at least one of a silicon oxide layer or a high-k dielectric layer (e.g., an aluminum oxide layer or a hafnium oxide layer).

A conductive layer may be formed in the gate regions 334 through the isolation trenches T. The conductive layer may be formed using an ALD process. In other words, the conductive layer may be formed using the solid sources (e.g., WClₓ) by the substrate-treating apparatus 1 according to some embodiments of the inventive concepts. The conductive layer outside the gate regions 334 may be removed to form electrodes 330 in the gate regions 334, respectively. The electrodes 330, the buffer dielectric layer 332, the insulating layers 335, and the insulating patterns 337 may provide a stack structure ST. A plurality of stack structures ST may be formed on the substrate 310. The electrodes 330 of each of the stack structures ST may include a ground selection line GSL, word lines WL, and a string selection line SSL.

According to some embodiments of the inventive concepts, the process gas of which the amount is substantially uniform may be supplied regardless of a process time. Embodiments of the inventive concepts may be applied to various processes using the solid source, and the solid source may include at least one selected from a group consisting of various kinds of materials, e.g., PDMAT, HfCl₄, and WClₓ.

According to some embodiments of the inventive concepts, the difference between the reaction rates of the solid sources in the reaction space may be reduced or compensated to obtain the uniform composition process gas. For example, the reaction rate of the solid source provided in the upstream sub-reaction space near to the start point of the flow of the gases may be greater than that of the solid source provided in the downstream sub-reaction space distant from the start point of the flow of the gases, and thus the solid source of the upstream sub-reaction space may be exhausted before exhaustion of the solid source of the downstream sub-reaction space. According to some embodiments of the inventive concepts, the amount of the solid source of the upstream sub-reaction space may be greater than that of the solid source of the downstream sub-reaction space, or the reaction rate of the solid source of the downstream sub-reaction space may be greater than that of the solid source of the upstream sub-reaction space. Thus, the difference between the reaction rates may be reduced or compensated.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

1. A semiconductor fabrication apparatus comprising:
a plurality of reaction containers coupled together to provide a plurality of sequential respective stages in a process of generating a process gas for semiconductor fabrication; and
each reaction container including a respective semiconductor fabrication solid source material in a respective configuration that is different than in others of the reaction containers.

2. The apparatus of claim 1 wherein the respective configuration is defined by physical dimensions including a total initial mass of the respective semiconductor fabrication solid source material and an effective surface area of the respective semiconductor fabrication solid source material exposed to the process in the reaction container.

3. The apparatus of claim 2 wherein at least one of the physical dimensions is different in all of the reaction containers and another of the physical dimensions is equal in all of the reaction containers.

4. The apparatus of claim 3 wherein the effective surface area comprises a specified particle size of the semiconductor fabrication solid source material in the respective reaction container.

5. The apparatus of claim 1 wherein each of the reaction containers further includes:
an inlet conduit configured to conduct a first composition of the process gas from upstream in the process to the respective stage; and
an outlet conduit configured to provide a second composition of the process gas generated by a reaction of the first composition of the process gas with the respective semiconductor fabrication solid source material in the respective reaction container to downstream in the process.

6. The apparatus of claim 5 wherein the process gas further comprises an inert carrier gas provided to the inlet conduit of a farthest upstream one of the reaction containers in the process.

7. The apparatus of claim 1 wherein a farthest downstream one of the reaction containers in the process is configured to couple to a process chamber configured to house a semiconductor substrate.

8. The apparatus of claim 7 wherein the farthest downstream one of the reaction containers provides the process gas to the process chamber at a substantially constant composition (+/−5%) until completion of the process.

9. The apparatus of claim 3 wherein the at least one of the physical dimensions is selected to compensate for a change in a composition of the process gas during the process.

10. The apparatus of claim 1 wherein the plurality of reaction containers comprises a respective plurality of reaction spaces housed within a single removable canister.

11. The apparatus of claim 10 wherein the plurality of reaction spaces are coupled together in a vertically stacked arrangement on one another within the single removable canister.

12. The apparatus of claim 10 wherein the plurality of reaction spaces are horizontally spaced apart from one another within the single removable canister.

13. The apparatus of claim 1 wherein the plurality of reaction containers comprises a plurality of separate removable canisters coupled in series with one another.

14. The apparatus of claim 2 wherein upstream ones of the reaction containers in the process are configured with a greater initial mass of the respective semiconductor fabrication solid source material compared to an initial mass of the respective semiconductor fabrication solid source material in downstream ones of the reaction containers in the process.

15. The apparatus of claim 2 wherein upstream ones of the reaction containers in the process are configured with a greater effective surface area of the respective semiconductor fabrication solid source material compared to the effective surface area of the respective semiconductor fabrication solid source material in downstream ones of the reaction containers in the process.

16. A semiconductor fabrication process canister comprising:
a plurality of reaction containers coupled together in series to provide a plurality of sequential respective stages in a process of generating a process gas, wherein the plurality of sequential respective stages is configured with a sequence of decreasing initial masses of semiconductor fabrication solid source material.

17. The canister of claim 16 wherein a respective effective surface of the semiconductor fabrication solid source material exposed to the process in each of the plurality of sequential respective stages is about equal.

18. A semiconductor fabrication process canister comprising:
a plurality of reaction containers coupled together in series to provide a plurality of sequential respective stages in a process of generating a process gas, wherein the plurality of sequential respective stages are configured with a sequence of increasing effective surface area of semiconductor fabrication solid source material exposed to the process in each of the plurality of sequential respective stages.

19. The canister of claim 18 wherein the respective sequence of increasing effective surface area comprises a respective sequence of increasing semiconductor fabrication solid source material specified particle size in each of the plurality of sequential respective stages.

20. The canister of claim 19 wherein a respective initial mass of the semiconductor fabrication solid source material in each of the plurality of sequential respective stages is about equal.

21.-39. (canceled)
